(19) United States
(12) Patent Application Publication
(10) Pub. No.: US 2002/0027189 A1
(43) Pub. Date: Mar. 7, 2002

(54) Solid-state image pick-up device and image pick-up method therefor

(75) Inventors: Ichiro Murakami, Tokyo (JP); Yasutaka Nakashiba, Tokyo (JP)

Correspondence Address: YOUNG & THOMPSON, 745 SOUTH 23RD STREET 2ND FLOOR, ARLINGTON, VA, 22202

(73) Assignee: NEC Corporation, Tokyo (JP)

(21) Appl. No.: 09/985,884

(22) Filed: Nov. 6, 2001

Related U.S. Application Data
(62) Division of application No. 09/251,484, filed on Feb. 17, 1999.

(30) Foreign Application Priority Data
Feb. 18, 1998 (JP) 35594/1998

(51) Int. Cl. H01L 27/00

(52) U.S. Cl. 250/208.1

(57) ABSTRACT

In a solid-state CCD image pick-up device with improved dynamic range and saturation variations, a signal charge that is obtained from a photoelectric conversion element that accumulates an electrical charge in response to incident light is transferred to a horizontal transfer section via a vertical transfer section and, by varying the electrical charge accumulation time of the photoelectric conversion elements, it is possible to achieve photoelectric conversion elements that have an apparent difference in sensitivity.

### BACKGROUND OF THE INVENTION

1. Field of the Invention

The present invention relates to a solid state image pick-up device.

2. Description of the Related Art

In solid-state CCDs (charge-coupled devices) for image pick-up in the past, the accumulated electrical charge output from photoelectric conversion sections disposed in two dimensions is sequentially output by either an in-line transfer method or progressive transfer method so as to output the image pick-up results. FIG. 11 is a plan view that shows this type of CCD solid-state image pick-up device. As shown in this drawing, a CCD solid-state image pick-up device 1 is formed by photoelectric conversion sections 2, which are disposed in a matrix arrangement and which have disposed between them vertical transfer elements 3, with a horizontal transfer 4 at the bottom edge of these vertical transfer elements 3. In this arrangement, a photoelectric conversion section 2 performs a photoelectric conversion on light incident thereto, thereby generating an accumulated electrical charge. Each of the vertical transfer elements 3 is driven, for example, by a four-phase drive pulse, so that the accumulated charge on each of the photoelectric conversion sections 2 is read out at a fixed period, the thus readout accumulated electrical charges being sequentially transferred to the horizontal transfer elements 4 are driven, for example, by a two-phase drive pulse, so that the accumulated charges that are transferred by the vertical transfer elements 3 are sequential transferred to in the direction of, and output from, an electrical charge detection section 5. The electrical charge detection section 5 stores these accumulated charges, via an output gate HOG, in a floating diffusion section FD, these being then output via an amplifier circuit 6 as an electrical signal. The electrical charge detection section 5 has sequentially formed in it adjacent to the floating diffusion section FD a reset gate RG and a reset drain RD, the accumulated charge on the floating diffusion section FD being discharged if necessary. By doing this, in the solid-state CCD image pick-up device 1, the accumulated electrical charges generated by each of the photoelectric conversion sections 2 are converted to electrical signals and output.

In current solid-state CCD image pick-up devices, because of a reduction in the chip size and the cell size, accompanying a reduction in the cell size the photo-electric conversion sections and vertical transfer elements become small, this resulting in a reduction in dynamic range. There is therefore a need to improve the dynamic range.

One method to do so was proposed by Kokubuchi et al, in an 1995 IEEE Workshop preprint collection titled “¼ Inch NTSC Format Hyper-D IL-CCD,” in which a high-sensitivity photoelectric conversion section and low-sensitivity photoelectric conversion section are disposed in neighboring manner, an image signal that is output from the solid-state CCD image pick-up device 1 being processed by an external circuit. By setting the electrical charge accumulation times for the neighboring photoelectric conversion sections 2 so as to be different, a high-sensitivity photoelectric conversion section and low-sensitivity photoelectric conversion section are formed. By forming one pixel by a pair consisting of a neighboring high-sensitivity photoelectric conversion section and low-sensitivity photoelectric conversion section, the image signals obtained from the high-sensitivity and low-sensitivity photoelectric conversion sections are added in an external circuit. When doing this, the image signal that is obtained from the high-sensitivity photoelectric conversion section is sliced and added by using a prescribed slice level.

In the above-noted method, however, it is necessary to output the high-sensitivity image signal and the low-sensitivity image signal from the solid-state CCD image pick-up device, this resulting in the problem of the configuration of the solid-state CCD image pick-up device becoming commensurately complex. While there is a method of outputting the image signals from a single solid-state CCD image pick-up device and processing them separately, in this case if an attempt is made to obtain image pick-up results of the same resolution, it is necessary to double the bandwidth of the amplifier circuit 6, and another problem is the external circuitry becomes complex.

Another known method, as shown in FIG. 12, is that method excessive electrical charge caused by high-intensity light is ejected in the substrate direction, so that a clipping effect is obtained.

The above-noted method is as follows. In a solid-state image pick-up device having a vertical overflow drain structure that performs clipping for each photosensitive pixel by means of charge ejection to the substrate, an electrical charge that is read out from a high-sensitivity photoelectric conversion section A and an electrical charge that is read out from a low-sensitivity photoelectric conversion section B are transferred so as to alternate within the horizontal CCD, after which they are transferred in the horizontal CCD in the direction of an amplifier section. When this is done, by means of the vertical overflow drain structure, in the high-sensitivity photoelectric conversion section A, the electrical charges that is generated by the high-intensity signal are each clipped to a maximum electrical charge established by the vertical overflow drain structure (this being referred to hereinafter as the amount of charge at the knee point).

Thereafter, the addition is performed of the electrical charge generated by the A pixel and the electrical charge generated by the B pixel.

However, when performing clipping of a high-intensity signal by using this above-noted vertical overflow drain structure, if there is nonuniformity in the injection profile between pixels in the photodiode n-type region and p-type well below this n-type region, there will be variation in the knee point potential from pixel to pixel. Because of this effect, when a high-intensity signal is received, there is a pixel-to-pixel variation in the photodiode saturation charge amount. This effect manifests itself in an actual image as the problem of fixed pattern noise from white variations caused by saturation.

The method of using a high-sensitivity photoelectric conversion section and a low-sensitivity photoelectric conversion section is known from, for example, the Japanese Unexamined Patent Publication (KOKAI) No. 9-116815, which is directed to a solid-state image pick-up device.

Accordingly, it is an object of the present invention to provide an improvement in the above-noted problems with the prior art, and in particular to provide a solid-state image pick-up device that, when a pair of pixels formed by a high-sensitivity photoelectric conversion section and a low-sensitivity photoelectric conversion section is used to improve the dynamic range, this improvement in dynamic range is achieved while enabling a simplification of the overall configuration.

### SUMMARY OF THE INVENTION

In order to achieve the above-noted object, the present invention makes use of basic technical constitution described below.

Specifically, a first aspect of a solid-state image pick-up device according to the present invention is a solid-state image pick-up device configured so as to send a signal charge that is obtained from an photoelectric conversion element in response to incident light to a charge detection section, via a transfer section comprising transfer elements, said solid-state image pick-up device comprising: blank transfer section that is provided between said transfer element which receives a signal charge that is obtained from said photoelectric conversion element and said a charge detection section; and means for clipping an excessive electrical charge of said signal charge, this clipping being performed by said means provided in said blank transfer section.

A second aspect of the present invention is a solid-state image pick-up device configured so as to send a signal charge that is obtained from a photoelectric conversion section that stores an electrical charge in response to incident light to a horizontal transfer section, via a vertical transfer section, this solid-state image pick-up device being configured so as to obtain photoelectric conversion elements that have an apparent difference in sensitivity, by causing the charge accumulation time of the above-noted photoelectric conversion elements to be variable.

A third aspect of the present invention is a solid-state image pick-up device which is provided with a photoelectric conversion element having a high sensitivity with respect to incident light and a photoelectric conversion element having a low sensitivity with respect to incident light, a signal charge that is obtained from the above-noted photoelectric conversion elements being sent via a vertical transfer section to a horizontal transfer section, and the electrical charge accumulation time of the photoelectric conversion element with the lower sensitivity being caused to vary by means of a substrate shutter.

In a fourth aspect of the present invention, the above-noted high-sensitivity photoelectric conversion elements and low-sensitivity photoelectric conversion elements are disposed alternately in the horizontal direction.

In a fifth aspect of the present invention, the above-noted high-sensitivity photoelectric conversion elements and low-sensitivity photoelectric conversion elements are disposed alternately in the vertical direction.

In a sixth aspect of the present invention, the above-noted high-sensitivity photoelectric conversion elements and low-sensitivity photoelectric conversion elements are disposed alternately in a checkered pattern.

In a seventh aspect of the present invention, the means for clipping the above-noted excessive electrical charge is a vertical overflow drain.

In a eighth aspect of the present invention, means for clipping excessive charge uses a narrow channel effect.

A nineth aspect of the present invention is said low-sensitivity photoelectric conversion elements comprising high-sensitivity photoelectric conversion element and a light-reducing filter being disposed on said high-sensitivity photoelectric conversion element.

An image-pickup method in a solid-state image-pickup device according to the present invention, is a method for a solid-state image pick-up device which converts an electrical charge accumulated in a photoelectric conversion element to an electrical signal, whereby a vertical overflow drain shutter is used to vary an amount of electrical charge that is accumulated in said photoelectric conversion element, thereby broadening the dynamic range.

### BRIEF DESCRIPTION OF THE DRAWINGS

FIG. 1 is a plan view that shows the first example of a solid-state CCD image pick-up device according to the present invention.

FIG. 2 is a graph that shows characteristics of the high-sensitivity photoelectric conversion section of the solid-state CCD image pick-up device of FIG. 1.

FIG. 3 is a graph that shows the characteristics of the low-sensitivity photoelectric conversion section of the solid-state CCD image pick-up device of FIG. 1.

FIG. 4 is a graph that shows the overall characteristics of the solid-state CCD image pick-up device of FIG. 1, as obtained from the characteristics shown in FIG. 2 and FIG. 3.

FIG. 5 is a plan view, a cross-sectional view, and a potential diagram that show the overflow drain of the first embodiment of the present invention.

FIG. 6 is a cross-sectional view that shows the horizontal transfer element and charge detection section of the solid-state CCD image pick-up device of FIG. 1.

FIG. 7 is a signal waveform diagram that shows the drive signal of the solid-state CCD image pick-up device of FIG. 1.

FIG. 8 is a drawing that illustrates the operation of the solid-state CCD image pick-up device of FIG. 1.

FIG. 9 is a plan view that shows the second embodiment of a solid-state CCD image pick-up device according to the present invention.

FIG. 10 is a plan view that shows the second embodiment of a solid-state CCD image pick-up device according to the present invention.

FIG. 11 is a plan view that shows a solid-state CCD image pick-up device of the past.

FIG. 12 is a plan view that shows a solid-state CCD image pick-up device of the past.

FIG. 13(a) shows a sectional view of the vertical overflow drain shutter.

FIG. 13(b) is a graph which shows the potential distribution for the depth at the photoelectric detection (PD) area.

### DESCRIPTION OF THE PREFERRED EMBODIMENTS

Embodiments of a solid-state CCD image pick-up device according to the present invention are described below in detail, with references being made to relevant accompanying drawings.

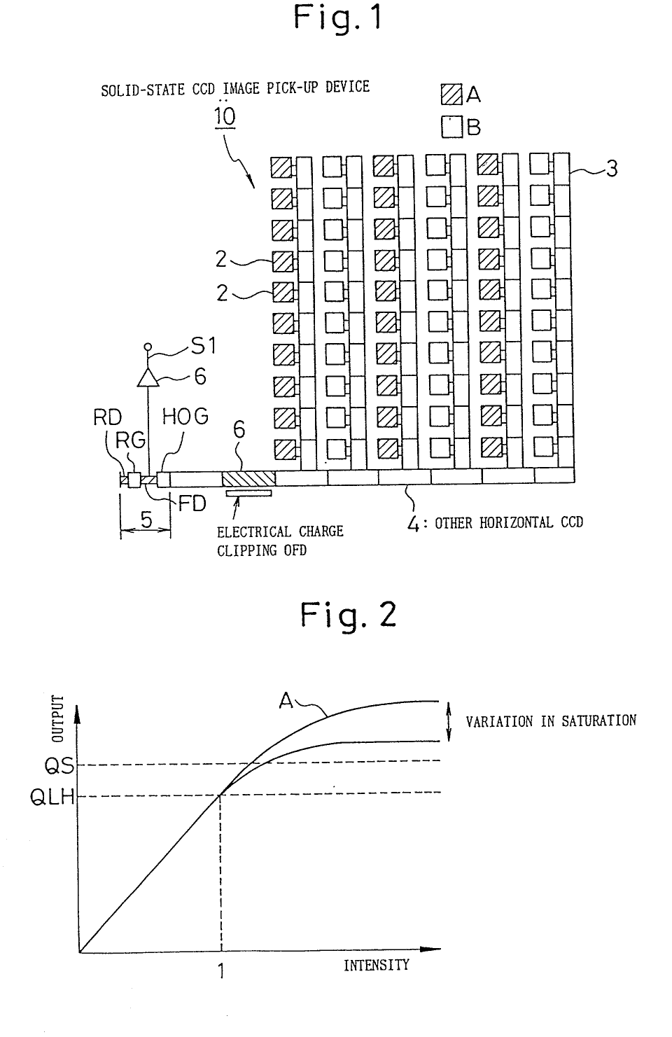

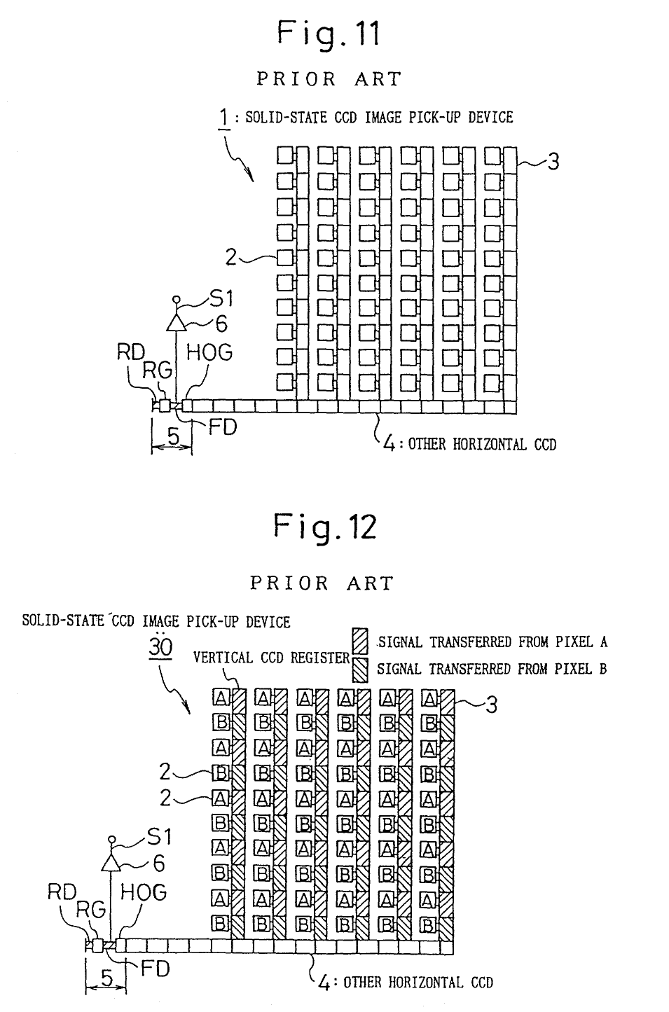

FIG. 1 is a plan view that shows the first embodiment of a solid-state CCD image pick-up device 10 according to the present invention, by way of comparison with the device that is shown in FIG. 11. In the configuration that is shown in FIG. 1, elements that are the same as in FIG. 11 have been assigned the same reference numerals, and are not explicitly described herein.

This solid-state CCD image pick-up device 10 has a vertical stripe light-reducing filter disposed on the image pick-up surface, whereby high-sensitivity photoelectric conversion elements A, indicated by hatching lines, and low-sensitivity photoelectric conversion elements B, are formed alternately in the horizontal direction. That is, the light-reducing filter has a region of high transmissivity that passes almost all the incident light and a region of low transmissivity that reduces the amount of light to 1/N, these regions being formed with a pitch that is the formation pitch of the photoelectric conversion elements 2, the light-reducing filter being supported by the image pick-up surface of the solid-state CCD image pick-up device 10 so that the regions of high transmissivity and regions of low transmissivity thereof are each caused to be in opposition to the photoelectric conversion elements 2.

Additionally, an overflow drain OFD is provided at one arbitrary location of the blank transfer elements of the horizontal CCD, near the electrical charge detection section 5 shown in FIG. 1. The reference numeral 6 denotes the transfer section at which the OFD is formed.

In a CCD image pick-up device configured as described above, the horizontal transfer element 4 are such that the accumulated electrical charge A output from a high-sensitivity photoelectric conversion element A (hereinafter referred to as a high-sensitivity accumulated charge) and the accumulated electrical charge B output form the low-sensitivity photoelectric conversion element B (hereinafter referred to as a low-sensitivity accumulated charge) are continuously output from the horizontal transfer element 4, and in this solid-state CCD image pick-up device 10 these continuous high-sensitivity accumulated charges A and low-sensitivity accumulated charges B are added so as to generate the image pick-up result for one pixel.

That is, as shown in FIG. 2, in the solid-state CCD image pick-up device, after this high-sensitivity accumulated charge A changes in amount of charge in response to the amount of incident light, saturation occurs at a prescribed boundary value. In FIG. 2, QLH is the amount of electrical charge that can be accumulated at the transfer section at which the OFD is formed, and QS is the saturation charge amount of the photoelectric conversion element 2.

In FIG. 2, the reason the saturation level differs depending upon the individual photoelectric conversion element is that the threshold value of read-out voltage of the transfer gate is different for each photoelectric conversion element 2.

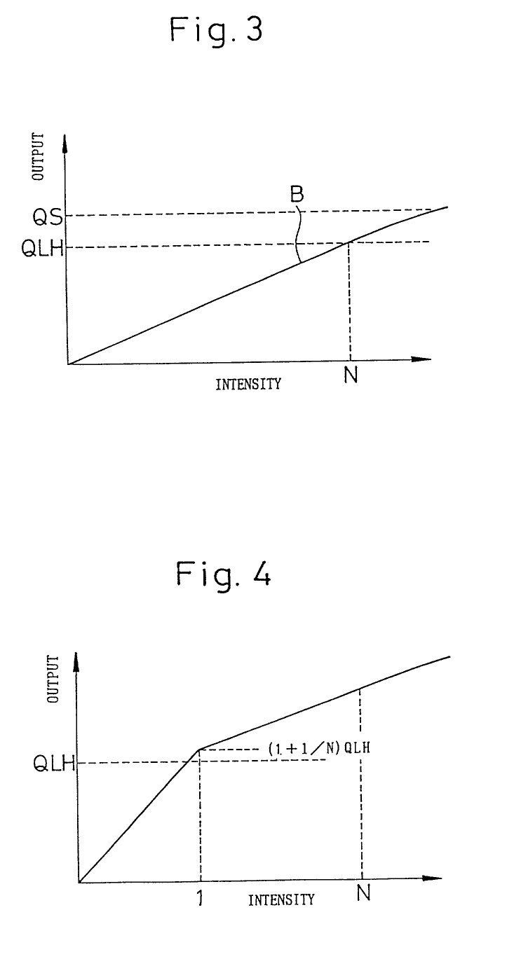

In contrast to the above, as shown in FIG. 3, the low-sensitivity accumulated charge B corresponds to the location of the light-reducing filter at which the transmissivity is 1/N, so that the amount of incident light corresponding to the saturation level is N times the amount of incident light for saturation in the case of the high-sensitivity accumulated charge. Because of this, in the solid-state CCD image pick-up device 10, after a prescribed OFD slices the high-sensitivity accumulated charge A, it is added to the low-sensitivity accumulated charge B and, as shown in FIG. 4, input-output characteristics are obtained that exhibit an improved dynamic range.

Next, the method of configuring the OFD used in the present invention will be described.

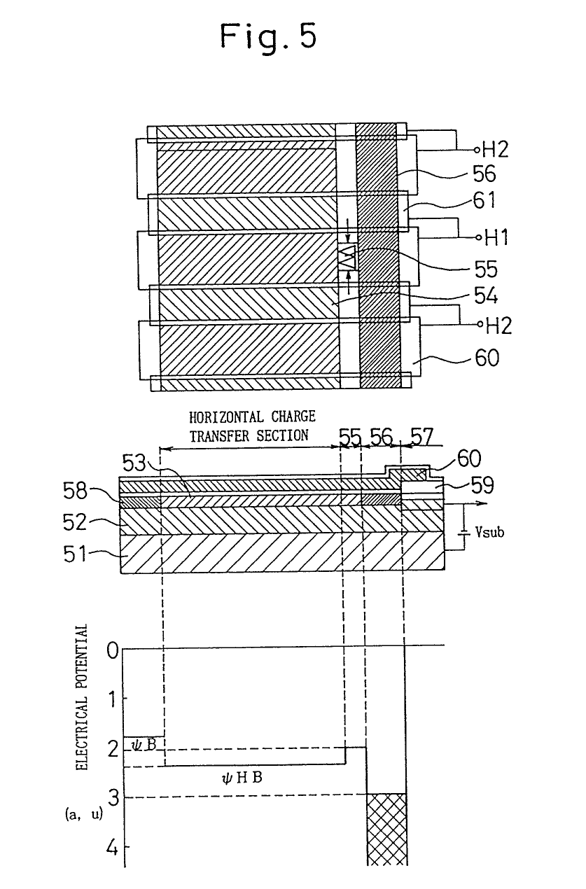

FIG. 5 is an enlarged view of one part of a horizontal CCD that includes one transfer element within horizontal CCD in which is provided an OFD.

In FIG. 5, the reference numeral 51 denotes an n-type semiconductor substrate, 52 is a p-type well, 53 is an n-type semiconductor region, 54 is an n-type semiconductor region, and 59 is an insulation layer, these being provided in this sequence. The n-type semiconductor region 53 form a channel. Additionally, a p-type semiconductor region 58 is provided at the side of the n-type semiconductor region 53, this serving as a channel stop.

In the OFD shown in FIG. 5, using the narrow channel effect, the potential barrier formed by the n-type semiconductor region 55 establishes the prescribe width between the two barriers, the potential barrier φ B in the n-type semiconductor region 53 being lower than the potential barrier φ HB set up by the channel step. Neighboring the potential barrier formed by the n-type semiconductor region 55 are provided an n⁺-type semiconductor region 56, which ejects unnecessary electrical charges to the substrate, and a bus line wiring forming region 57. Additionally, above the n-type semiconductor region 53, the p-type semiconductor region 58, the n-type semiconductor region 55, and the n⁺-type semiconductor region 56 is formed a first layer electrode 1PS 60 and a second layer electrode 2PS 61.

Specifically, in the solid-state CCD image pick-up device 10, by setting the OFD barrier potential φ B to a prescribed value, the amount of electrical charge QLH at the transfer part having the OFD is limited, the result being that the accumulated charge that is output from the photoelectric conversion element A is sliced to this electrical charge amount of QLH. When this is done, by setting the amount of electrical charge QLH that can be accumulated, excessive accumulated charge is ejected from the unwanted charge ejection part via the barrier in the OFD.

The amount of electrical charge QLH that can be accumulated in the horizontal transfer electrode LH on one transfer part within the horizontal CCD having an OFD becomes smaller than the amount of electrical charge QH that can be accumulated by other electrodes of the horizontal transfer elements 4, and the internal potential φ B in the potential barrier part of the n-type semiconductor region 54 is set so that the conditions QLH<QH and QLH<QS are satisfied.

Although the OFD potential barrier 55 in the present invention is provided by using a narrow channel effect, it is also possible to provide a potential barrier by injection of a conventional p-type impurity.

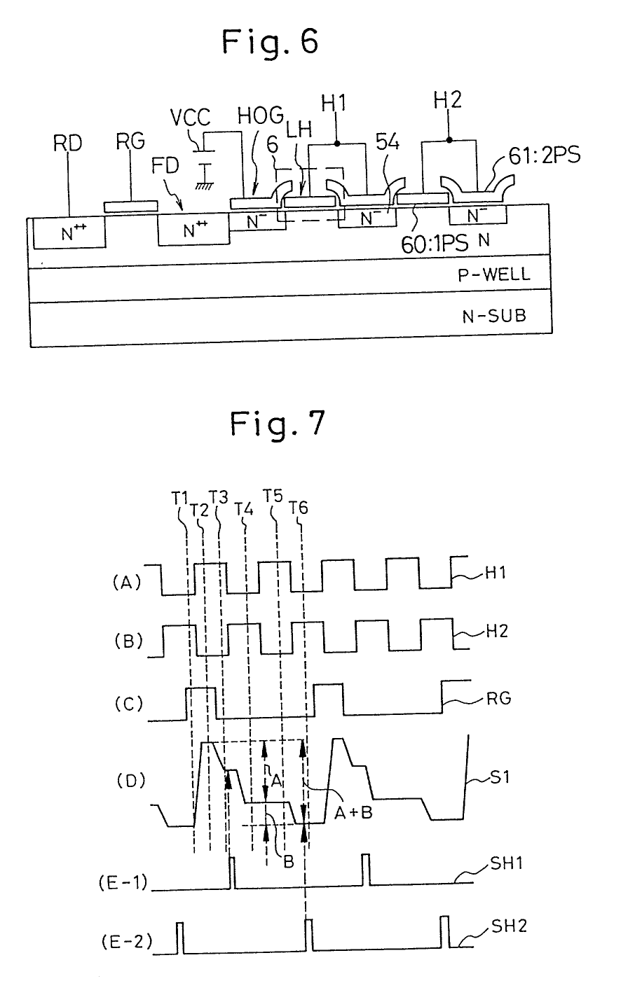

FIG. 6 shows a horizontal transfer element and charge detection section in the solid-state CCD image pick-up device that is shown in FIG. 1. The area in FIG. 6 surrounded by a broken line indicates transfer part and upper electrode at which the OFD is formed. As can be seen in the cross-section view in FIG. 6, after forming a first layer electrode 1PS 60 with a pitch that corresponds to the interval of the vertical transfer elements 3, ion implantation of a p-type impurity is done so as to form an n-type semiconductor region 54 that has a shallow internal potential between the first layer electrodes 1PS 60. Then, a second layer electrode 2PS 61 is formed by partial lamination between the first layer electrode 1PS 60, thereby connecting adjacent first layer and second layer electrodes.

Next, an example of a charge detection section 5 will be described. The reset gate RG of the charge detection section 5 is formed at the time of forming the first layer electrode 1PS 60 or the second layer electrode 2PS 61 on the horizontal transfer elements, and the output gate HOG is formed at the time of forming the second layer electrode 2PS 61. The charge detection section 5 has the potential on both sides of the reset gate set so as to be deep, by separately implanting an n-type impurity in the region between the reset gate and the output gate HOG. By doing this, the region between the reset gate RG and the output gate HOG is allotted to the floating diffusion section FD and another region is allotted to the reset drain RD.

Additionally in this example, by applying a voltage VCC to HOG that is approximately the same as the voltage when H2 is on, the potential of the potential barrier which faces the transfer section provided with the OFD is kept not to be below φ B.

Additionally, in contrast to a conventional solid-state CCD image-pickup device, which sequentially outputs image signals that correspond to each of the photoelectric conversion elements, the timing of setting the reset gate RG to on is established in units of two periods of the horizontal transfer pulse, thereby causing the addition, in the floating diffusion section FD, of the high-sensitivity and low-sensitivity accumulated charges A and B.

That is, as shown in FIG. 7, the horizontal transfer element 4 is driven by the a two-phase drive pulse H1 and H2 (FIGS. 7 (A) and (B)), the levels of which change in a complimentary manner, so as to perform sequential transfer of the accumulated charge. In the charge detection section 5, a reset pulse is generated (FIG. 7 (C)) and the reset gate RG is driven by this reset pulse, so that there is a rise in the signal levels every two periods of the drive pulses H1 and H2, and so that a signal level rise occurs between the rising edges of these drive pulses H1 and H2.

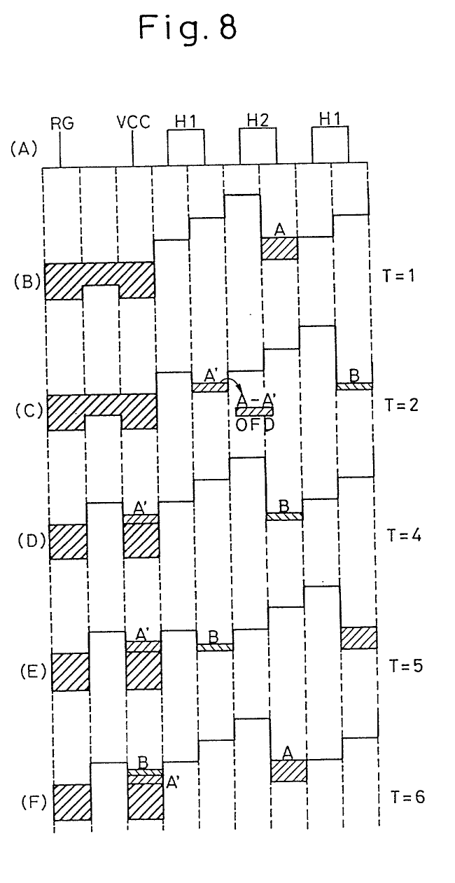

By doing this, as shown in FIG. 8, at the time T1, which is immediately after the rising edge of the reset pulse (FIGS. 8 (A) and (B)), the horizontal transfer element 4 and the charge detection section 5 discharge from the reset drain RD the charge that had been accumulated for the immediately previous pixel and which had been held by the floating diffusion section FD.

Then, at the time T3, which is immediately before the levels of the drive pulses H1 and H2 are switched, the level of the reset pulse is low level, so that the a switch is made to the condition in which it is possible to hold the accumulated charge, causing the charge to be held. Then, in a transfer element which is provided with an overflow drain OFD, at times T2 and T3, in the period when H1 is on and H2 is off, excessive charge is ejected to the charge ejection part, thereby achieving slicing of the electrical charge that is generated by a high-intensity signal to a prescribed QLH amount.

By doing the above, when the drive pulses H1 and H2 change signal levels thereafter, as shown in FIG. 8 (D) for the time T3, the horizontal transfer element 4 and the charge detection section 5 transfer and hold the high-sensitivity accumulated charge A via HOG, after which, in response to a switching of the signal levels of the drive pulses H1 and H2 (FIGS. 8 (E) and (F), times T4 and T5), the low-sensitivity accumulated charge B is transferred to this floating diffusion section FD.

In this embodiment, therefore, in the period of time in which the reset gate RG is at a raised level (corresponding to the time T1), the image signal S1 (FIG. 7 (D)) that is output from the amplifier circuit 6 is held at the reset level, in the period of time in which the high-sensitivity accumulated charge A and low-sensitivity accumulated charge B are held in the floating diffusion section FD (corresponding to the time T6), the holding is made to a signal level that is the sum of the sliced high-sensitivity accumulated charge A and the low-sensitivity accumulated charge B.

By doing the above in this embodiment, in a correlated double sampling circuit that processes the output signal of the solid-state CCD image pickup device 10, sample-and-hold pulses SH1 and SH2 (FIGS. 7 (E-1) and (E-2)) which correspond to times T3 and T6 each perform a sample-and-hold operation on the image signal S1, after which the results of the sample-and-hold, are subtracted, thereby enabling the achievement of imaging results with a large dynamic range, by adding the accumulated charges A and B.

In the above-noted configuration, the light that is incident to the solid-state CCD image pick-up device 10, by passing through a vertical stripe light-reducing filter, is caused to be incident alternately with respect to the photoelectric conversion sections 2, which are continuous in the horizontal direction, this incident light being photoelectricly converted thereat, so as to generate an accumulated electrical charge. By doing this, there are formed alternately in the horizontal direction high-sensitivity photoelectric conversion section at which the incident light is not reduced and low-sensitivity photoelectric conversion sections at which the incident light is reduced by a light-reducing filter.

The high-sensitivity and low-sensitivity accumulated charges A and B, which are generated at these high-sensitivity and low-sensitivity photoelectric conversion sections, are read out at the vertical transfer element 3 at a prescribed period, after which transfer is performed in the direction of the horizontal transfer element 4. By doing this in the solid-state CCD image pick-up device 10, the high-sensitivity and low-sensitivity accumulated charges A and B that are adjacent to each other in the horizontal direction, are output alternately to the charge detection section 5.

When this is done, at one transfer section within the horizontal CCD at which an OFD is provided, the narrow channel effect causes the formation of an OFD potential barrier and an unwanted charge ejection section, the potential φ B of the potential barrier being held at a fixed value (FIG. 5). The result of this action is that, because the amount of charge that can be accumulated at a transfer section at which an OFD is provided is established as being a prescribed charge QLH (FIG. 2), excessive accumulated charge that exceeds this charge amount of QLH is allowed to overflow from the potential barrier to the unwanted charge ejection section, discharge of charge at the OFD part from the potential barrier to the unwanted charge ejection section being done during the period of time between times T2 and T3, as shown in FIG. 7. The result of this is that the high-sensitivity and low-sensitivity accumulated charges A and B are limited to the amount of charge QLH by the transfer section that is provided with an OFD, these then being transferred to the charge detection section 5.

Additionally, in the charge detection section 5, the reset pulse (FIG. 7 (C)) that is applied to the reset drain RD rises every two periods of the drive pulses H1 and H2, and the accumulated charge of the floating diffusion section FD is discharged each two periods, thereby causing the high-sensitivity accumulated charge A to be held in FD, and the low-sensitivity accumulated charge B is transferred to FD (FIGS. 8 (D) through (F)). This causes the high-sensitivity and low-sensitivity accumulated charges A and B, which are continuously transferred to the charge detection section 5, to be added at the floating diffusion section FD, so that in the solid-state CCD image pick-up device 10 two continuous photoelectric conversion sections 2 are assigned to one pixel, thereby broadening the dynamic range.

The change in the accumulated charge at the floating diffusion section FD is thus output, via the amplifier circuit 6, as the image signal S1 (FIG. 7 (D)). In a correlated doubling sampling circuit, the first sample-and-hold result is obtained at the timing of the discharge of the charge accumulated at the floating diffusion section FD (FIG. 7 (E-1)), and also the second sample-and-hold results is obtained at the timing of the accumulation of the high-sensitivity and low-sensitivity charges A and B at the floating diffusion section FD (FIG. 7 (E-2)), thereby enabling the achievement of imaging results with a large dynamic range.

According to the configuration as described above, the first benefit is that, because the high-sensitivity accumulated charge A and the low-sensitivity accumulated charge B are continuously input to the charge detection section 5, the amount of charge that can be held at a transfer section at which an OFD is provided is set to limit this amount of holdable charge, and the discharge of accumulated charge at the floating diffusion section FD is performed every two periods, the high-sensitivity accumulated charge A and the low-sensitivity accumulated charge B being added, using a simple configuration, it is possible to output an image pick-up result in which the high-sensitivity accumulated charge A and low-sensitivity accumulated charge B, which are adjacent in the horizontal direction, as assigned to one pixel, thereby providing a broadening of the dynamic range.

The second benefit is that, unlike the prior art, it is not necessary to output the high-sensitivity and low-sensitivity image pick-up signals from separate solid-state CCD image pick-up devices, thereby avoiding the accompanying complexity of the solid-state CCD image pick-up device.

The third benefit is that, whereas the clipping action that was performed in the past separately at the photoelectric conversion elements resulted in variations in the readout voltage threshold between elements, this resulting in pattern noise, this is avoided by performing the clipping at one and the same location.

Note that, the aforementioned narrow-channel-effect used in the present invention refers the effect with which a barrier potential of the barrier for over-flow drain can be controlled by narrowing a width of both ends of channel stoppers of the over-flow drain and by controlling the concentration of impurities used therein.

In the present invention, the regions as shown by the numerical references 53 and 55 as shown in FIG. 5, show N-type semiconductor regions, respectively and by forming this, the gate electrode which has been used for controlling a potential on barrier in conventional devices, is no more required.

Further, in the present invention, a process for forming N⁻ region therein is not required so that the barrier potential of the barrier can be easily controlled with simple configuration and with cheaper cost.

On the other hand, the narrow-channel-effect per se is already known to public, since it has been published in, for example, “1.3M Pixcel CCD Image Sensor, NEC Technical Journal (No. 3, Vol. 50, 1997, Masayuki Furumiya et al.).

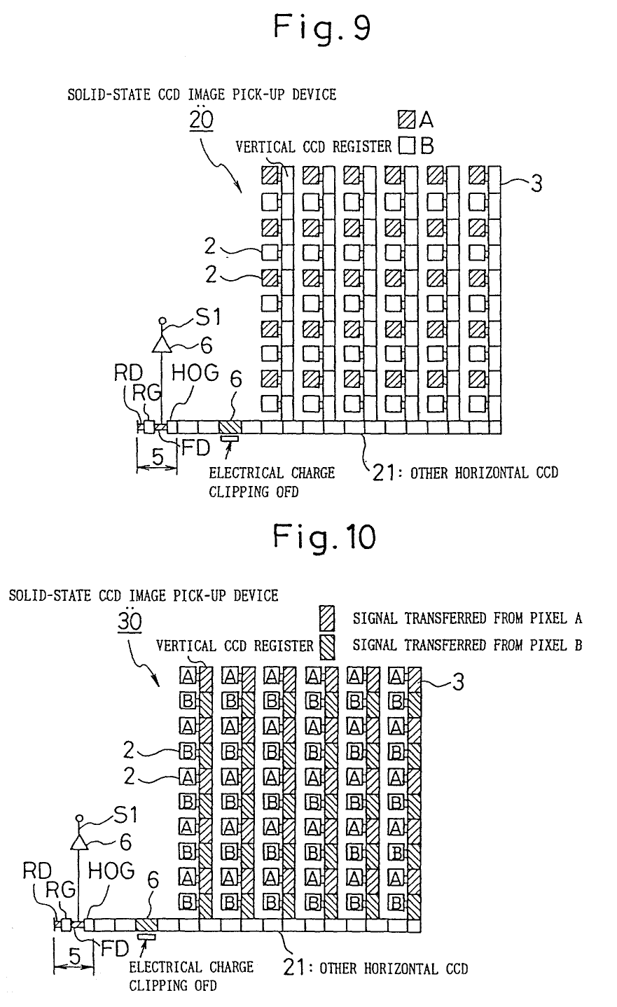

FIG. 9 is a plan view that shows the second embodiment of a solid-state CCD image pick-up device according to the present invention. In this solid-state CCD image pick-up device 20, the arrangement of the light-reducing filter is in the vertical direction instead of the horizontal direction, as it was in the first embodiment, thereby resulting in the formation of a high-sensitivity photoelectric conversion section and a low-sensitivity photoelectric conversion section B that are continuous in the vertical direction.

A horizontal transfer element 21 has transfer electrodes that are formed with a pitch that is ½ half of the formation pitch of the vertical transfer elements 3, a drive pulse inputting one line of high-sensitivity accumulated charge A from the vertical transfer elements 3, at which point this high-sensitivity accumulated charge A is transferred for one transfer period, toward the charge detection section 5, after which one line of low-sensitivity accumulated charge B is input from the vertical transfer elements 3.

By doing this, in the solid-state CCD image pick-up device 20, when an accumulated charge is input to the horizontal transfer elements 21, two lines of accumulated charge A and B, which are continuous in the vertical direction, are arranged to alternate continuously, these accumulated charges A and B being processed in the charge detection section 5 in the same manner as described with regard to the first embodiment of the present invention.

In this embodiment, by performing the above-noted action, two photoelectric conversion sections 2 that are continuous in the vertical direction form one pixel, thereby resulting in the output of an image pick-up result that has a broadened dynamic range.

According to the configuration shown in FIG. 9, even if the high-sensitivity photoelectric conversion sections A and low-sensitivity photoelectric conversion section B are formed in the vertical direction, the same effect as noted with regard to the first embodiment can be achieved.

FIG. 10 is a plan view that shows a third embodiment of a solid-state CCD image pick-up device according to the present invention, and in this solid-state CCD image pick-up device 30 the charge accumulation time of the photoelectric conversion sections 2 is varied, so as to alternately form high-sensitivity photoelectric conversion sections A and low-sensitivity photoelectric conversion sections B, these alternating in the vertical direction.

Specifically, a vertical overflow drain (VOD) shutter is used to perform removal of charge to the substrate after a prescribed period of time, after which charge is accumulated. Then, after the charge accumulation time is completed, readout is performed to a vertical CCD register from only the photoelectric conversion sections A, via the transfer gate section. Then, at the photoelectric conversion sections B, so that the charge accumulation time is longer than that of the photoelectric conversion sections A, a substrate shutter is not used, accumulation being performed until the next vertical CCD register readout, including the accumulation time of the photoelectric conversion sections A, after which when the accumulation period has been completed readout is performed to the vertical CCD register from only the photoelectric conversion sections B, via the transfer gate.

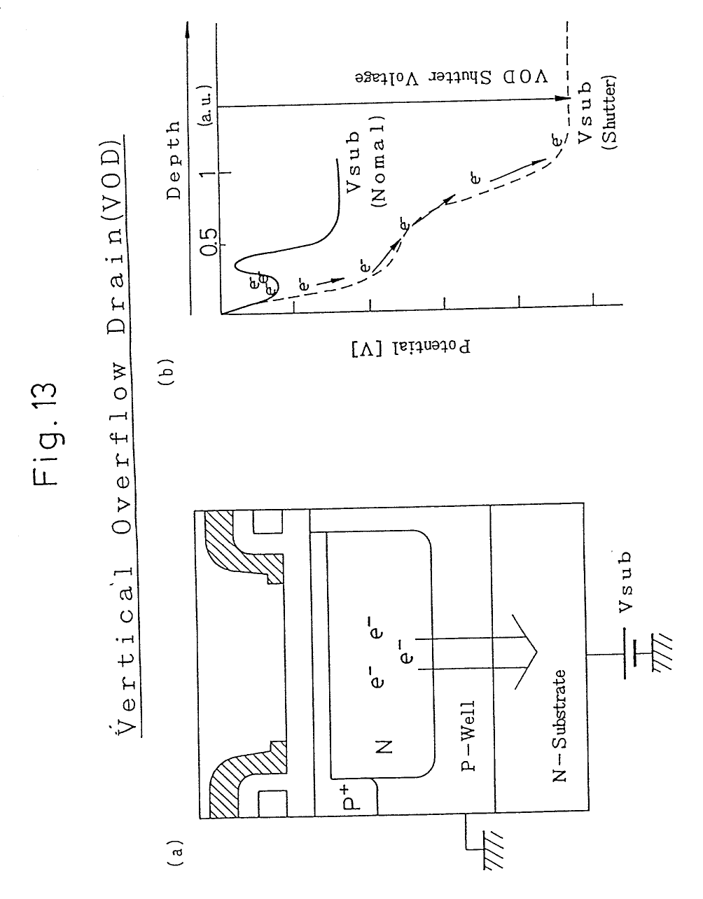

FIG. 13 explains the function of the VOD shutter, where the potential distribution is shown for depth at the photoelectric detection (PD) area. For the charge storage mode (normal condition), the voltage of 5V-10V is applied for Vsub. When the VOD shutter voltage is applied for Vsub (shutter condition), all charge stored in PD area are swept out to the substrate.

Thus, by varying the electrical charge accumulation time at the photoelectric conversion sections, rather than using a light-reducing filter, to form high-sensitivity and low-sensitivity photoelectric conversion sections, it is possible to achieve the same effect as with the earlier described embodiments of the present invention.

One method of varying the electrical charge accumulation time at the photoelectric conversion sections 2 is to use a vertical overflow drain shutter to arbitrarily set the accumulation starting time, and in addition to this method, by varying the timing of readout of the signal from one of the solid-state image pick-up devices, it is possible to vary the relative accumulation times of the two, thereby enabling the output of two or more types of signals with differing sensitivities from a single solid-state image pick-up device 30.

According to the present invention as described above, by disposing high-sensitivity and low-sensitivity photoelectric conversion sections adjacent to each other, and by providing a OFD at one location, this being at a so-called horizontal blank transfer element at which there is no direct transfer of electrical charge from a vertical transfer element, near the amplifier of the horizontal transfer element, it is not necessary to have separate solid-state CCD image pick-up devices for the high-sensitivity image signal and the low-sensitivity image signal, thereby achieving a commensurate elimination of complexity in the solid-state CCD image pick-up devices. Additionally, although in the present invention one image signal is extracted from the CCD and processed separately, this does not require to double the bandwith of the amplifier circuits such as was required in the past.

Also, because clipping was done separately for each photoelectric conversion element, resulting in variations in the readout threshold value that manifest themselves as fixed-pattern noise, the present invention performs these clipping operations also at one and the same location, thereby solving this clipping-related problem.

According to the present invention as described in detail above, the accumulated electrical charge that is output from a high-sensitivity photoelectric conversion section is limited to a prescribed level, after which this is added to a low-sensitivity accumulated charge in a floating diffusion section, thereby achieving, with a simple configuration, an image pick-up result with an improved dynamic range.

Furthermore, the present invention is not restricted the above-noted embodiments, and can be the subject of a various changes to the embodiments, within the technical conceptual scope of the present invention.

What is claimed is:

1. A solid-state image pick-up device configured so as to send a signal charge that is obtained from an photoelectric conversion element in response to incident light to a horizontal transfer section, via a vertical transfer section, said solid-state image pick-up device being configured so as to obtain photoelectric conversion elements that have an apparent difference in sensitivity, by causing the charge accumulation time of said photoelectric conversion elements to vary.

2. A solid-state image pick-up device comprising a photoelectric conversion element that has a high sensitivity with respect to incident light and a photoelectric conversion element that has a low sensitivity with respect to incident light, said image pick-up device being configured so that a signal charge that is obtained from said photoelectric conversion element is transferred to a horizontal transfer section via a vertical transfer section, a substrate shutter being used to vary the electrical charge accumulation time of said low-sensitivity photoelectric conversion element.
